(19) United States
(12) Patent Application Publication
(10) Pub. No.: US 2022/0041513 A1
(43) Pub. Date: Feb. 10, 2022

(54) CHEMICAL VAPOUR INFILTRATION OR DEPOSITION PROCESS

(71) Applicant: SAFRAN CERAMICS, LE HAILLAN (FR)

(72) Inventor: Jean-François Daniel René POTIN, MOISSY-CRAMAYEL (FR)

(21) Appl. No.: 17/413,296

(22) PCT Filed: Nov. 25, 2019
(86) PCT No.: PCT/FR2019/052794

§ 371 Date: Jun. 11, 2021

(30) Foreign Application Priority Data
Dec. 14, 2018 (FR) 1872948

(51) Int. Cl. C04B 35/626; C04B 35/52; C04B 35/83; C23C 16/26; C23C 16/04; F16D 69/02

(52) U.S. Cl. CPC C04B 35/6267; C04B 35/52; C04B 35/83; C23C 16/26; C04B 2235/614; F16D 69/023; C04B 2235/5244; C04B 2235/5248; C04B 2235/5256; C23C 16/045

(57) ABSTRACT

A process for chemical vapor infiltration or deposition, includes forming pyrocarbon in the porosity of a porous substrate or on a surface of a substrate, the substrate being placed in a reaction chamber and the pyrocarbon being formed from a gas phase introduced into the reaction chamber, the gas phase including at least one pyrocarbon precursor compound and carbon dioxide.

### TECHNICAL FIELD

The present invention relates to a chemical vapor infiltration or deposition process in which pyrocarbon is formed from a gas phase comprising a pyrocarbon precursor compound and carbon dioxide.

### PRIOR ART

It is known to coat or densify substrates with pyrocarbon (also known as pyrolytic carbon) by placing the substrates in a furnace into which a reactive gas containing a pyrocarbon precursor consisting of a hydrocarbon is introduced. The pressure and temperature in the furnace are controlled to produce the pyrocarbon coating or matrix by decomposition of the hydrocarbon precursor.

The effluent gas containing reaction by-products is extracted from of the furnace.

The reaction by-products include organic compounds that have a relatively high solidification temperature, in particular polycyclic aromatic hydrocarbons (PAHs) such as naphthalene, pyrene, anthracene or acenaphthylene.

By condensation, these reaction by-products form tars which tend to be deposited in the furnace outlet pipes as the flue gas cools. These tars are also found in the pumping device, for example in the vacuum pump oil or in the steam ejector condensate.

It is therefore desirable to improve the pyrocarbon formation processes by limiting the generation of PAHs.

### DISCLOSURE OF THE INVENTION

According to a first aspect, the invention is aimed at a process of chemical vapor infiltration or deposition, comprising at least:
forming pyrocarbon in the porosity of a porous substrate or on a surface of a substrate, the substrate being placed in a reaction chamber and the pyrocarbon being formed from a gas phase introduced into the reaction chamber, this gas phase comprising at least one pyrocarbon precursor compound and carbon dioxide.

The pyrocarbon precursor compound is a compound known per se for obtaining pyrocarbon by chemical vapor infiltration or deposition technique. The introduction of carbon dioxide CO₂ into the reaction chamber in addition to the pyrocarbon precursor compound advantageously allows the production of molecular hydrogen during the formation of the pyrocarbon, which limits the production of PAH.

In an example embodiment, a volume content of carbon dioxide in the gas phase of less than or equal to 15% is imposed, this content being taken at the time the gas phase is introduced into the reaction chamber.

It is advantageous to limit the carbon dioxide content in the gas phase in order to limit its oxidizing character.

In particular, the carbon dioxide content by volume in the gas phase can be less than or equal to 10%, for example less than or equal to 7%, or even less than or equal to 5%. The carbon dioxide content by volume in the gas phase can be greater than or equal to 2%, for example greater than or equal to 3%.

In particular, the volume content of carbon dioxide in the gas phase can be comprised between 2% and 15%, for example between 2% and 10%, for example between 2% and 7%. In particular, the volume content of carbon dioxide in the gas phase can be comprised between 3% and 15%, for example between 3% and 10%, or even between 3% and 7%.

In an example embodiment, the pyrocarbon precursor compound is a hydrocarbon.

In particular, the pyrocarbon precursor compound can be a linear hydrocarbon.

The use of a linear hydrocarbon is advantageous because it improves the kinetics of molecular hydrogen formation and thus further limits PAH production.

However, the invention is not limited to the use of a hydrocarbon as pyrocarbon precursor compound. Alternatively, the pyrocarbon precursor compound can be an alcohol or a polyalcohol. “Alcohol” is understood to mean a compound having a single alcohol function. “Polyalcohol” is understood to mean a compound having several alcohol functions.

The invention is also aimed at a process for manufacturing part made of composite material with a matrix at least partially of pyrocarbon, the process comprising at least:
densifying the porous substrate forming a fibrous preform of the part to be obtained with a pyrocarbon matrix phase by chemical vapor infiltration by performing a process as described above.

The fibrous preform can be formed from threads of ceramic or carbon material.

In an example embodiment, the fibrous preform has an annular shape and is made of carbon fiber.

In an example embodiment, the fibrous preform can be formed in one piece by three-dimensional weaving or from a plurality of two-dimensional fibrous strata.

In an example embodiment, the part is a friction part, for example a brake disc such as an aircraft brake disc.

Alternatively, the friction part can be a brake disc for a land vehicle, in particular an automobile, or a friction part other than a disc, in particular a brake pad.

### DESCRIPTION OF THE EMBODIMENTS

The steps of an embodiment in which a porous substrate is densified by a pyrocarbon matrix phase will now be described. In this case, a chemical vapor infiltration (CVI) technique is implemented.

According to an alternative, the pyrocarbon can be formed on the external surface of the substrate. In this case, a chemical vapor deposition (CVD) technique is used.

The following description describes an example of a CVI technique but applies mutatis mutandis to the case where a CVD technique is implemented. The person skilled in the art knows how to adapt the operating conditions from CVI to CVD or from CVD to CVI.

The porous substrate is first formed during a first step. The porous substrate has an accessible porosity that is intended to be filled in whole or in part by the pyrocarbon from the gas phase.

The porous substrate can be a fibrous preform in the shape of a composite material part to be obtained. The fibrous preform is intended to constitute the fibrous reinforcement of the part to be obtained.

The fibrous preform may comprise a plurality of ceramic or carbon threads or a mixture of such threads. For example, silicon carbide threads supplied by the

Japanese company NGS under the reference “Nicalon”, “Hi-Nicalon” or “Hi-Nicalon Type S” can be used. The carbon threads that can be used are, for example, supplied under the name Torayca T300 3K by the company Toray.

The fibrous preform can be obtained from at least one textile operation using threads.

According to an example, the fibrous preform can be made by superimposing strata cut from a fibrous texture made of carbon precursor threads, bonding the strata together, for example by needling, and transforming the precursor into carbon by heat treatment. The preform can also be made directly from strata of fibrous texture made of carbon threads which are superimposed and bonded together, for example by needling.

An annular preform can also be made by winding a helical fabric of carbon precursor threads into superposed turns, bonding the turns together, for example by needling, and transforming the precursor by heat treatment. Reference may be made, for example, to the documents U.S. Pat. Nos. 5,792,715; 6,009,605 and 6,363,593.

According to an alternative, the fibrous preform can be obtained by multilayer or three-dimensional weaving of such threads.

“Three-dimensional weaving” or “3D weaving” means weaving method in which at least some of the warp threads interlink weft threads on several weft layers. A reversal of roles between warp and weft is possible in the present text and should be considered as covered by the claims as well.

The fibrous preform can, for example, have a multi-satin weave, i.e., be a fabric obtained by three-dimensional weaving with a plurality of layers of weft threads whose basic weave of each layer is equivalent to a conventional satin-type weave but with certain points of the weave binding the layers of weft threads together.

Alternatively, the fibrous preform may have an interlock weave. “Interlock weave or fabric” means a 3D weave in which each layer of warp threads interlinks a plurality of layers of weft threads, with all of the threads in the same warp column having the same movement in the weave plane. Various multi-layer weaving methods that can be used to form the fibrous preform are described in WO 2006/136755.

It is also possible to start from fibrous textures such as two-dimensional fabrics or unidirectional webs, and to obtain the fibrous preform by draping such fibrous textures over a form. These textures can optionally be interlinked, for example by sewing or implanting threads to form the fibrous preform.

Once obtained, the porous substrate is densified by a pyrocarbon matrix phase obtained from the gas phase. The matrix coats the threads of the fibrous preform. The threads of the preform are present in the matrix.

The invention can be implemented in a known CVI facility suitable for pyrocarbon densification including an additional introduction line for injecting carbon dioxide gas into the reaction chamber. The carbon dioxide can be introduced into the reaction chamber by per se known means commonly used in CVI to introduce the precursor in a gaseous state. The pyrocarbon precursor compound and the carbon dioxide can be introduced separately (through different injection points) into the reaction chamber. According to an embodiment, the pyrocarbon precursor compound and the carbon dioxide can be introduced into the reaction chamber directly as a mixture (through the same injection point). Preferably, the mixing of the pyrocarbon precursor compound and the carbon dioxide is carried out before the temperature of the reaction chamber is raised so that chemical vapor infiltration or deposition can be carried out.

The gas phase comprises (i) at least one pyrocarbon precursor compound in a gaseous state, (ii) carbon dioxide in a gaseous state, and optionally (iii) a diluent gas such as a neutral gas like argon. The gas phase may consist essentially of said at least one pyrocarbon precursor compound, carbon dioxide, and the diluent gas optionally present.

The proposed simplified mechanism of pyrocarbon formation is shown below in the case where the precursor compound is a hydrocarbon. In the chemical equations below, CₓH_{y} denotes the hydrocarbon precursor of pyrocarbon and the radical compounds are marked with the symbol *.

CₓH_{y}+CO₂->CO+OH*+CₓH_{y-1}*

OH*+CₓH_{y-1}*->H₂O+CₓH_{y-2}

H₂O+CO->CO₂+H₂.

As indicated in the chemical equations above, carbon dioxide initially reacts with the hydrocarbon CₓH_{y} in the gas phase to obtain carbon monoxide and radical reaction intermediates OH* and CxH_{y-1}*. These OH* and CxH_{y-1}* reaction intermediates then react together to form CₓH_{y-2} which has a C═C double bond and from which the pyrocarbon is obtained. The carbon monoxide reacts with the water vapor present in the gas phase to form molecular hydrogen, which limits the formation of PAHs.

When the precursor compound is a hydrocarbon, the latter may have at least two carbon atoms. The number of carbon atoms in the hydrocarbon can be comprised between 2 and 5, and for example can be equal to 3. The hydrocarbon may, for example, be propane. Alternatively, the pyrocarbon precursor compound can be an alcohol or a polyalcohol. The alcohol or polyalcohol can be C₂ to C₆. For example, ethanol can be used as the pyrocarbon precursor.

During the formation of the pyrocarbon, the temperature in the reaction chamber can be comprised between 980° C. and 1050° C., for example between 1000° C. and 1020° C., and the pressure in the reaction chamber can be comprised between 1 kPa and 2 kPa, for example between 1.3 kPa and 1.7 kPa.

During the formation of the pyrocarbon, a carbon dioxide content in the gas phase of at most 15% by volume can be imposed, this content being taken at the time of introduction of the gas phase into the reaction chamber.

The carbon dioxide content in the gas phase is, unless otherwise stated, equal to the following ratio [volume of carbon dioxide introduced into the reaction chamber]/[total volume of gas phase introduced into the reaction chamber].

The pyrocarbon matrix phase formed from the gas phase may occupy at least 50%, or even at least 75%, of the initial porosity of the porous substrate. The porous substrate can be fully densified by the pyrocarbon from this gas phase. Alternatively, only part of the matrix densifying the porous substrate can be formed by the pyrocarbon from this gas phase, the rest of the matrix having a different composition. The remainder of the matrix can, for example, be made of a ceramic material different from the pyrocarbon, of silicon carbide for example.

Regardless of the example embodiment considered (CVI or CVD), a plurality of substrates can be simultaneously treated by the gas phase in the same reaction chamber.

The expression “comprised between . . . and . . . ” should be understood as including the bounds.

1. A process for chemical vapor infiltration or deposition, comprising:
forming pyrocarbon in a porosity of a porous substrate or on a surface of a substrate, the substrate being placed in a reaction chamber and the pyrocarbon being formed from a gas phase introduced into the reaction chamber, said gas phase comprising at least one pyrocarbon precursor compound and carbon dioxide.

2. The process as claimed in claim 1, wherein a volume content of carbon dioxide in the gas phase of less than or equal to 15% is imposed, said content being taken at the time the gas phase is introduced into the reaction chamber.

3. The process as claimed in claim 2, wherein the volume content of carbon dioxide in the gas phase is less than or equal to 10%.

4. The process as claimed in claim 3, wherein the volume content of carbon dioxide in the gas phase is comprised between 2% and 7%.

5. The process as claimed in claim 1, wherein the pyrocarbon precursor compound is a hydrocarbon.

6. The process as claimed in claim 5, wherein the pyrocarbon precursor compound is a linear hydrocarbon.

7. The process as claimed in claim 1, wherein the pyrocarbon precursor compound is an alcohol or a polyalcohol.

8. A process for manufacturing part made of composite material with a matrix at least partially of pyrocarbon, the process comprising:
densifying a porous substrate forming a fibrous preform of the part to be obtained with a pyrocarbon matrix phase by chemical vapor infiltration by performing a process as claimed in claim 1.

9. The process as claimed in claim 8, wherein the part is a friction part.

10. The process as claimed in claim 9, wherein the part is a brake disc.
